(19) United States
(12) Patent Application Publication
(10) Pub. No.: US 2021/0257982 A1
(43) Pub. Date: Aug. 19, 2021

(54) RECEIVING DEVICE AND RECEIVING METHOD

(71) Applicant: FUJITSU LIMITED, Kawasaki-shi (JP)

(72) Inventors: DAISUKE USUI, Kawasaki (JP); MANABU YAMAZAKI, Fuchu (JP); Hirotomo Izumi, Kawasaki (JP)

(73) Assignee: FUJITSU LIMITED, Kawasaki-shi (JP)

(21) Appl. No.: 17/143,197

(22) Filed: Jan. 7, 2021

(30) Foreign Application Priority Data
Feb. 18, 2020 (JP) 2020-025710

(51) Int. Cl. H03G 3/30; H04L 17/16

(52) U.S. Cl. CPC H03G 3/3036; H04L 17/16

(57) ABSTRACT

A receiving device, includes a memory; and a processor coupled to the memory and configured to: when amplifying a multi-valued signal of a multi-valued modulation technique according to a control signal, acquire a first multi-valued signal before amplifying the multi-valued signal and a second multi-valued signal after amplifying the multi-valued signal, detect a first peak voltage of the first multi-valued signal, detect a second peak voltage of the second multi-valued signal, and control the control signal based on the first peak voltage and the second peak voltage such that a maximum amplitude of the second multi-valued signal and linearity of the second multi-valued signal are maintained.

### CROSS-REFERENCE TO RELATED APPLICATION

This application is based upon and claims the benefit of priority of the prior Japanese Patent Application No. 2020-25710, filed on Feb. 18, 2020, the entire contents of which are incorporated herein by reference.

### FIELD

The embodiments discussed herein are related to a receiving device and a receiving method.

### BACKGROUND

For example, a multi-valued modulation technique is adopted as a high-speed signal transmission method within or between data centers, Moreover, in a hyperscale data center expected in the future, for example, hundreds of thousands of optical transceivers are connected, and each transceiver is desired to have low power consumption.

Thus, future issues will be, for example, the linear amplification of a multi-valued signal and the maximization of signal amplitude. For example, in the case of four-level pulse amplitude modulation (PAM4) having signal levels of 0 to 3, transmission is performed using information at intermediate levels (1 and 2) as well, as illustrated in FIG. 10. Therefore, linear amplification that amplifies a signal while ensuring the linearity is desired.

Moreover, in the case of PAM4, the amplitude of the signal level is ⅓ the amplitude of the non-return-to-zero (NRZ) binary signal, and accordingly the difficulty of analog-to-digital conversion becomes higher. Therefore, in the front-end circuit of the receiving device, it is desired to maximize the signal amplitude such that sufficient amplification is achieved in a range in which the PAM4 signal is linear.

Thus, for example, there is a method of detecting two voltage levels of a signal by an amplitude information detector arranged in the subsequent stage of the amplifier and controlling a variable gain amplifier so as to achieve an appropriate degree of amplification on the basis of difference information on the voltage levels, In this method, for example, among the signal levels 0 to 3 of PAM4, the voltage level of the signal level 2 and the voltage level of the signal level 3 are detected, and these voltage levels of the signal level 2 and the signal level 3 are compared to adjust the amplitude for each signal level. Japanese Laid-open Patent Publication No. 2000-165457 is known as related art.

Examples of the related art include Japanese Laid-open Patent Publication No. 2000-165457.

### SUMMARY

According to an aspect of the embodiments, a receiving device, includes a memory; and a processor coupled to the memory and configured to: when amplifying a multi-valued signal of a multi-valued modulation technique according to a control signal, acquire a first multi-valued signal before amplifying the multi-valued signal and a second multi-valued signal after amplifying the multi-valued signal, detect a first peak voltage of the first multi-valued signal, detect a second peak voltage of the second multi-valued signal, and control the control signal based on the first peak voltage and the second peak voltage such that a maximum amplitude of the second multi-valued signal and linearity of the second multi-valued signal are maintained,

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is an explanatory diagram illustrating an example of a receiving device of the present embodiments;

FIG. 2 is a block diagram illustrating an example of a front-end (FE) circuit;

FIG. 3 is an explanatory diagram illustrating an example of gain-frequency characteristics of an amplification unit;

FIG. 4 is an explanatory diagram illustrating an example of gain adjustment that keeps a set gain amount while the set gain amount is within an allowable threshold value range;

FIG. 5 is an explanatory diagram illustrating an example of gain adjustment that lowers the set gain amount when the set gain amount exceeds a threshold value on a positive side;

FIG. 6 is an explanatory diagram illustrating an example of gain adjustment that raises the set gain amount when the set gain amount exceeds a threshold value on a negative side;

FIG. 7 is a flowchart illustrating an example of the processing operation of the FE circuit relating to an adjustment process;

FIG. 8 is an explanatory diagram illustrating an example of a receiving device of a comparative example;

FIG. 9 is an explanatory diagram illustrating an example of the amount of power consumption of each part in the receiving devices according to the embodiment and the comparative example; and

FIG. 10 is an explanatory diagram illustrating an example of each signal level of PAM4.

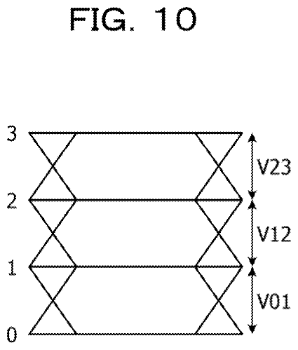

### DESCRIPTION OF EMBODIMENTS

However, the conventional method involves, for example, two or more high-precision amplitude information detectors that accurately detect the voltage level of the signal level 2 and the voltage level of the signal level 3, which are supposed to consume power. Besides, it is difficult to adjust the amplitude for each signal level so as to maintain the linear amplification and maximize the signal amplitude only on the basis of the difference in the voltage levels detected by the amplitude information detectors in the subsequent stage of the amplifier. In view of the above, it is desirable to provide a multi-valued signal receiving circuit and the like capable of adjusting the amplitude of a multi-valued signal for each signal level while suppressing power consumption.

Hereinafter, the embodiments of a multi-valued signal receiving circuit and the like disclosed in the present application will be described in detail based on the drawings. Note that the disclosed technology is not limited by each of the embodiments, Furthermore, each embodiment to be described below may also be combined as appropriate, without causing inconsistency.

### EMBODIMENTS

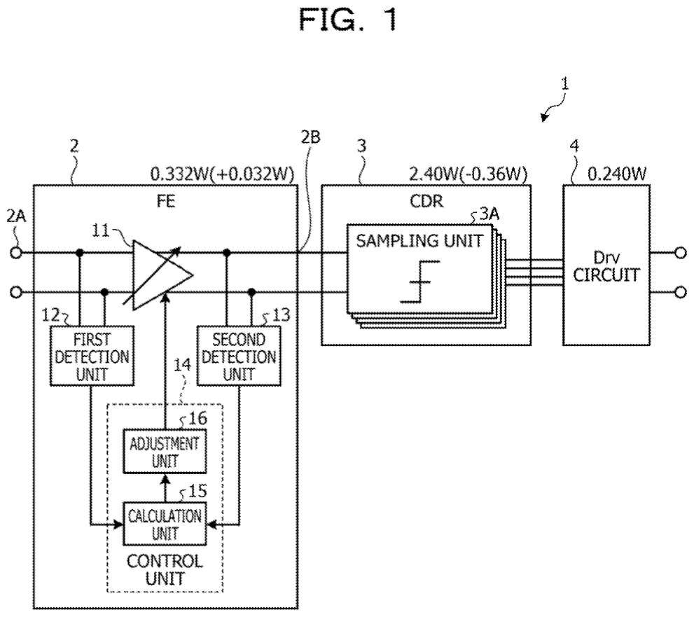

FIG. 1 is an explanatory diagram illustrating an example of a receiving device 1 of the present embodiments. The receiving device 1 illustrated in FIG. 1 includes a front-end (FE) circuit 2, a clock data recovery (CDR) circuit 3, and a driver (Drv) circuit 4. The FE circuit 2 is a circuit that amplifies an electrical signal of, for example, PAM4, which is a multi-valued signal of a multi-valued modulation technique. The CDR circuit 3 includes a sampling unit 3A that extracts a data signal from the electrical signal of PAM4 amplified by the FE circuit 2, and reproduces a clock signal from the data signal. The Drv circuit 4 drives and outputs the data signal based on the clock signal.

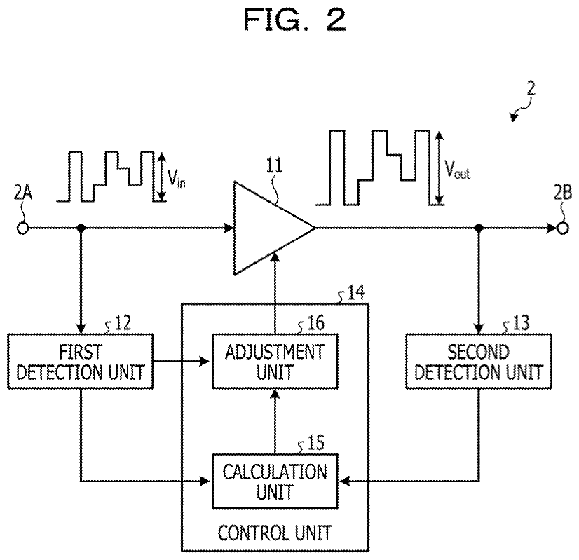

FIG. 2 is a block diagram illustrating an example of the FE circuit 2. The FE circuit 2 illustrated in FIG. 2 includes an input terminal 2A, an output terminal 26, an amplification unit 11, a first detection unit 12, a second detection unit 13, and a control unit 14. The input terminal 2A is a terminal that inputs the electrical signal of PAM4 to the FE circuit 2. The output terminal 26 is a terminal that outputs the electrical signal of PAM4 from the FE circuit 2.

The amplification unit 11 is an amplifier that is arranged between the input terminal 2A and the output terminal 26 and amplifies, for example, the electrical signal of PAM4 according to a control signal. The amplification unit 11 amplifies an electrical signal Vin of PAM4 before amplification according to the control signal, and outputs an electrical signal Vout of PAM4 after amplification. The first detection unit 12 is, for example, a peak detection circuit that detects a first peak voltage V1 of the electrical signal Vin of PAM4 before amplification at the input stage of the amplification unit 11. The second detection unit 13 is, for example, a peak detection circuit that detects a second peak voltage V2 of the electrical signal Vout of PAM4 after amplification at the output stage of the amplification unit 11.

Based on the first peak voltage V1 and the second peak voltage V2, the control unit 14 generates a control signal to control the gain of the amplification unit 11 such that the maximum amplitude and the linearity of the electrical signal Vout of PAM4 after amplification are maintained. The control unit 14 includes a calculation unit 15 and an adjustment unit 16.

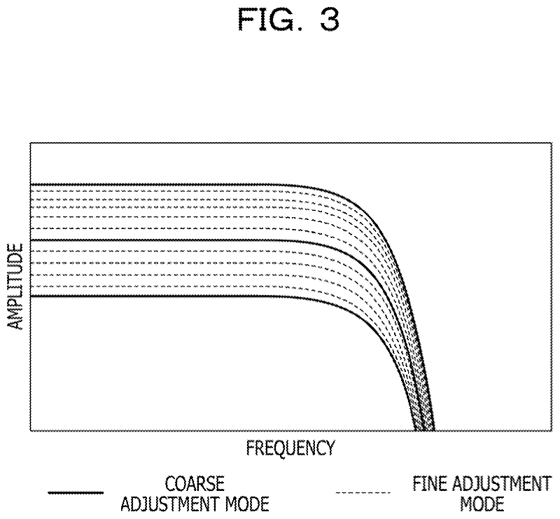

The calculation unit 15 calculates a calculated gain amount A2 of the amplification unit 11 based on (V2/V1) using the first peak voltage V1 and the second peak voltage V2. FIG. 3 is an explanatory diagram illustrating an example of gain-frequency characteristics of the amplification unit 11. The amplification unit 11 has gain-frequency characteristics in which the amplitude (gain amount) is adjusted according to the frequency. The adjustment unit 16 has a coarse adjustment mode and a fine adjustment mode as modes for adjusting a set gain amount A1. The coarse adjustment mode is a mode in which the set gain amount A1 is roughly adjusted at the time of initial setting. The fine adjustment mode is a mode in which the set gain amount A1 is finely adjusted in steps. The adjustment unit 16 acquires the set gain amount A1 of the amplification unit 11 and also acquires the calculated gain amount A2 calculated by the calculation unit 15. The calculated gain amount A2 is a gain amount of the amplification unit 11 obtained by computation. The adjustment unit 16 calculates a difference amount A3 based on |A2−A1|, which is the difference between the set gain amount A1 and the calculated gain amount A2, and determines whether or not the difference amount A3 is within an allowable threshold value range.

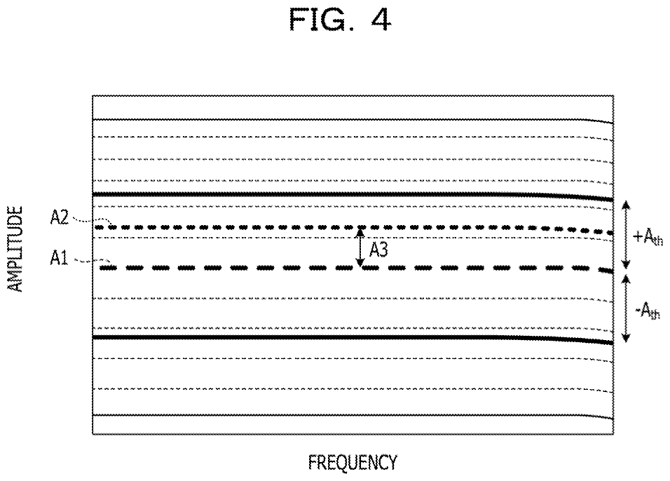

FIG. 4 is an explanatory diagram illustrating an example of gain adjustment that keeps the set gain amount A1 while the set gain amount A1 is within the allowable threshold value range. As illustrated in FIG. 4, the adjustment unit 16 generates a control signal to keep the set gain amount A1 when the difference amount A3 is within the allowable threshold value range, and inputs the control signal to the amplification unit 11. The allowable threshold value range is a range between a positive threshold value +Ath and a negative threshold value −Ath on the basis of a reference, in which the set gain amount A1 can be allowed.

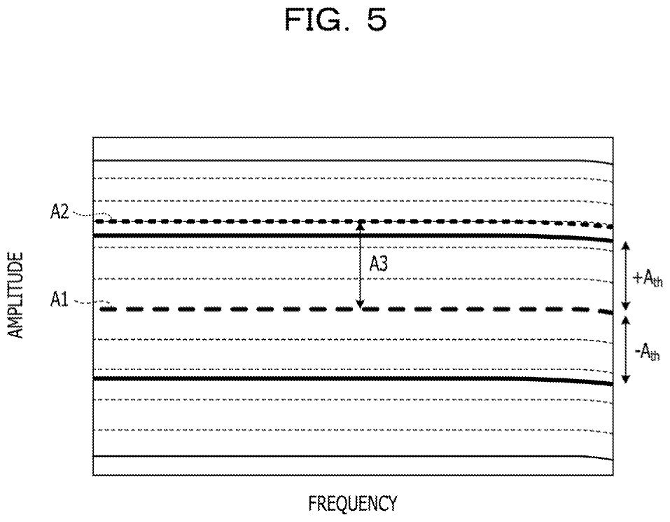

FIG. 5 is an explanatory diagram illustrating an example of gain adjustment that lowers the set gain amount A1 when the set gain amount A1 exceeds the threshold value +Ath on the positive side. As illustrated in FIG. 5, when the difference amount A3 exceeds the allowable threshold value range and exceeds the positive threshold value +Ath, the adjustment unit 16 generates a control signal to decrease the set gain amount A1 in steps in units of predetermined amounts of the fine adjustment mode, for example, to decrease the set gain amount A1 by one step, and inputs the control signal to the amplification unit 11. The amplification unit 11 adjusts the difference amount A3 such that the difference amount A3 falls within the allowable threshold value range, by lowering the signal level of the electrical signal of PAM4 according to the control signal.

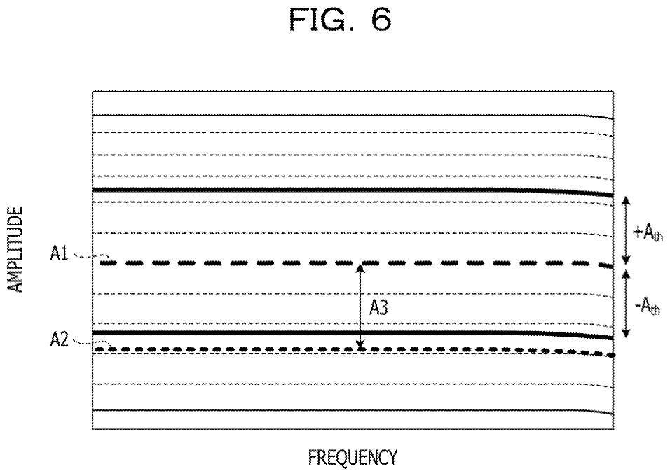

FIG. 6 is an explanatory diagram illustrating an example of gain adjustment that raises the set gain amount A1 when the set gain amount A1 exceeds the threshold value −Ath on the negative side. As illustrated in FIG. 6, when the difference amount A3 exceeds the allowable threshold value range and is less than the negative threshold value, the adjustment unit 16 generates a control signal to increases the set gain amount A1 in steps in units of predetermined amounts, for example, to increase the set gain amount A1 by one step, and inputs the control signal to the amplification unit 11. The amplification unit 11 adjusts the difference amount A3 such that the difference amount A3 falls within the allowable range, by raising the signal level of the electrical signal of PAM4 according to the control signal.

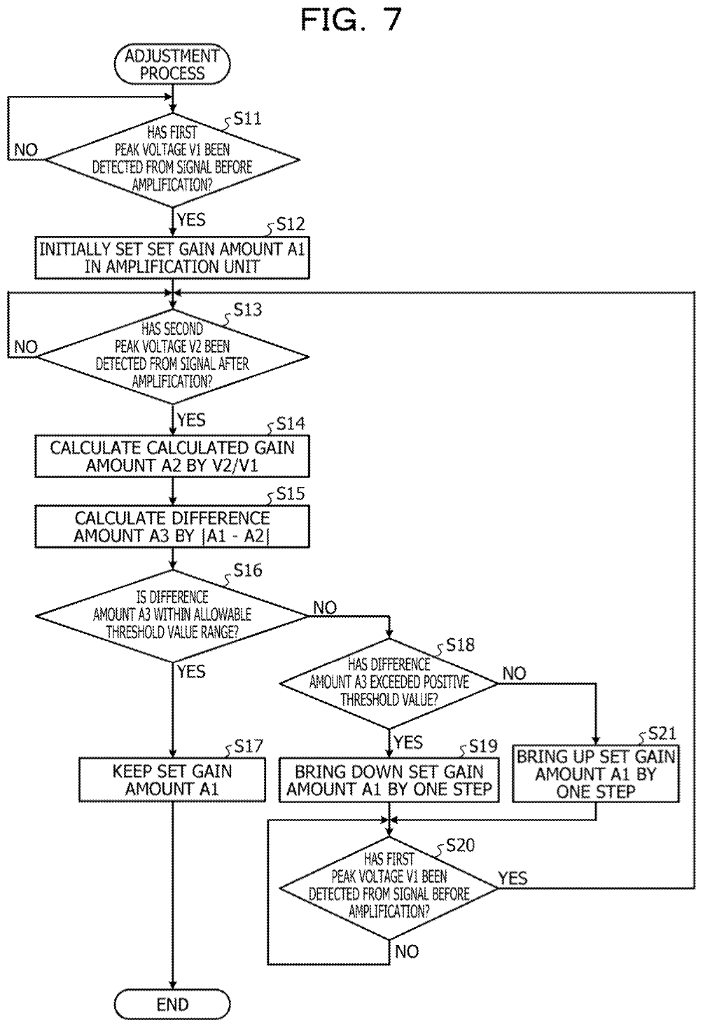

Next, an operation of the receiving device 1 according to the present embodiment will be described. FIG. 7 is a flowchart illustrating an example of the processing operation of the FE circuit 2 relating to an adjustment process. The first detection unit 12 in the FE circuit 2 determines whether or not the first peak voltage V1 has been detected from a part of the electrical signal Vin of PAM4 before amplification (step S11). When the first peak voltage V1 has been detected (step S11: Yes), the adjustment unit 16 in the FE circuit 2 initially sets the set gain amount A1 of the amplification unit 11 in the coarse adjustment mode (step S12). As a result, the amplification unit 11 amplifies the electrical signal of PAM4 before amplification based on the set gain amount A1, and outputs the electrical signal of PAM4 after amplification.

The second detection unit 13 in the FE circuit 2 determines whether or not the second peak voltage V2 has been detected from a part of the electrical signal Vout of PAM4 after amplification in the amplification unit 11 (step S13). The calculation unit 15 in the FE circuit 2 calculates the calculated gain amount A2 by the ratio between the first peak voltage V1 and the second peak voltage V2, which is (V2/V1) (step S14).

The adjustment unit 16 in the FE circuit 2 calculates the difference amount A3 by |A1−A2| based on the currently set gain amount A1 of the amplification unit 11 and the calculated gain amount A2 calculated by the calculation unit 15 (step S15). The adjustment unit 16 determines whether or not the difference amount A3 is within the allowable threshold value range (step S16).

When the difference amount A3 is within the allowable threshold value range (step S16: Yes), the adjustment unit 16 keeps the currently set gain amount A1 (step S17), and ends the processing operation illustrated in FIG. 7. When the first peak voltage V1 has not been detected from a part of the electrical signal of PAM4 before amplification (step S11: No), the first detection unit 12 proceeds to step S11 in order to determine whether or not the first peak voltage V1 has been detected from a part of the electrical signal Vin of PAM4 before amplification. When the second peak voltage V2 has not been detected from a part of the electrical signal of PAM4 after amplification (step S13: No), the second detection unit 13 proceeds to step S13 in order to determine whether or not the second peak voltage V2 has been detected.

When the difference amount A3 is not within the allowable threshold value range (step S16: No), the adjustment unit 16 determines whether or not the difference amount A3 has exceeded the positive threshold value (step S18). When the difference amount A3 has exceeded the positive threshold value (step S18: Yes), the adjustment unit 16 inputs a control signal to bring down the set gain amount A1 by one step in the fine adjustment mode, to the amplification unit 11 (step S19). As a result, the amplification unit 11 amplifies the electrical signal of PAM4 before amplification such that the electrical signal proceeds in a direction in which the difference amount A3 falls within the allowable range, by decreasing the set gain amount A1, and outputs the electrical signal of PAM4 after amplification. The first detection unit 12 determines whether or not the first peak voltage V1 has been detected from a part of the electrical signal Vin of PAM4 before amplification (step S20).

When the first peak voltage V1 has been detected (step S20: Yes), the adjustment unit 16 proceeds to step S13 in order to determine whether or not the second peak voltage V2 has been detected. When the first peak voltage V1 has not been detected (step S20: No), the adjustment unit 16 proceeds to step S20 in order to determine whether or not the first peak voltage V1 has been detected.

When the difference amount A3 has not exceeded the positive threshold value (step S18: No), the adjustment unit 16 finds that the difference amount A3 is less than the negative threshold value, and brings up the set gain amount A1 by one step in the fine adjustment mode (step S21). As a result, the amplification unit 11 amplifies the electrical signal of PAM4 before amplification such that the electrical signal proceeds in a direction in which the difference amount A3 falls within the allowable range, by increasing the set gain amount A1, and outputs the electrical signal of PAM4 after amplification. Then, the first detection unit 12 proceeds to step S20 in order to determine whether or not the first peak voltage V1 has been detected.

The FE circuit 2 keeps the set gain amount A1 of the amplification unit 11 when the difference amount A3 is within the allowable threshold value range. As a result, PAM4 that has the maximum signal amplitude and maintains the linearity may be obtained.

When the difference amount A3 is out of the allowable threshold value range and the difference amount A3 has exceeded the positive threshold value, the FE circuit 2 brings down the set gain amount A1 of the amplification unit 11 by one step. Then, the set gain amount A1 is adjusted until the difference amount A3 falls within the allowable threshold value range. As a result, PAM4 that has the maximum signal amplitude and maintains the linearity may be obtained.

When the difference amount A3 is out of the allowable threshold value range and the difference amount A3 does not exceed the positive threshold value, the FE circuit 2 finds that the difference amount A3 is less than the negative threshold value, and brings up the set gain amount A1 of the amplification unit 11 by one step. Then, the set gain amount A1 is adjusted until the difference amount A3 falls within the allowable threshold value range. As a result, PAM4 that has the maximized signal amplitude and maintains the linearity may be obtained.

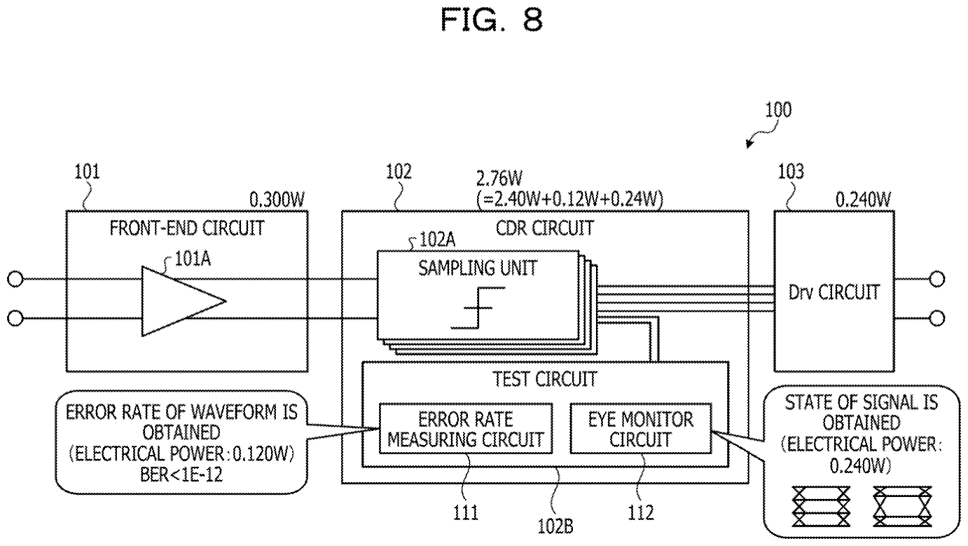

FIG. 8 is an explanatory diagram illustrating an example of a receiving device 100 of a comparative example. The receiving device 100 illustrated in FIG. 8 includes an FE circuit 101, a CDR circuit 102, and a Drv circuit 103. The FE circuit 101 includes an amplification unit 101A. The CDR circuit 102 includes a test circuit 102B in addition to a sampling unit 102A. The test circuit 102B includes an error rate measuring circuit 111 and an eye monitor circuit 112.

The error rate measuring circuit 111 measures the error rate of the output signal after amplification. The eye monitor circuit 112 monitors the eye-opening of the output signal after amplification. Then, the test circuit 102B feeds back the error rate measurement result and the eye-opening monitor result to the FE circuit 101. Thereafter, the FE circuit 101 adjusts the gain of the amplification unit 101A while observing the error rate such that the linearity of the signal and the maximization of the signal amplitude are maintained.

However, in the comparative example, since the error rate measuring circuit 111 and the eye monitor circuit 112 are arranged, more power consumption is involved, which leads to the expansion of the scale of the circuit.

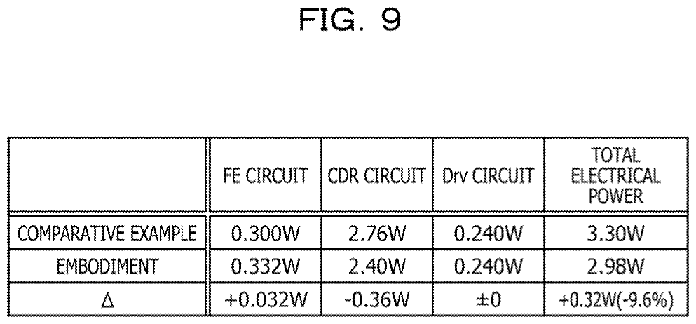

FIG. 9 is an explanatory diagram illustrating an example of the amount of power consumption of each part in the receiving devices 1 (100) according to the embodiment and the comparative example. It is assumed that, in the comparative example, the amount of power consumption of the FE circuit 101 is 0.300 W, the amount of power consumption of the CDR circuit 102 is 2.76 W, and the amount of power consumption of the Drv circuit 103 is 0.240 W. The amount of power consumption of the error rate measuring circuit 111 is 0.12 W, and the amount of power consumption of the eye monitor circuit 112 is 0.24 W. As a result, the total amount of power consumption of the comparative example is given as 3.30 W. On the other hand, in the present embodiment, it is assumed that the amount of power consumption of the FE circuit 2 is 0.332 W, the amount of power consumption of the CDR circuit 3 is 2.40 W, and the amount of power consumption of the Drv circuit 4 is 0.240 W. As a result, the total amount of power consumption of the embodiment is given as 2.98 W.

This means that, although the FE circuit 2 of the present embodiment includes the first detection unit 12, the second detection unit 13, and the control unit 14, the amount of power consumption may be reduced as compared with the test circuit 1028 of the comparative example. Therefore, in the receiving device 1 of the present embodiment, the total amount of power consumption may be reduced and the circuit scale may also be reduced as compared with the receiving device 100 of the comparative example.

Based on the first peak voltage V1 and the second peak voltage V2, the FE circuit 2 of the present embodiment controls the gain of the amplification unit 11 such that the maximum signal amplitude and the linearity of PAM4 after amplification are maintained. As a result, PAM4 that has the maximum signal amplitude and maintains the linearity while suppressing power consumption may be obtained.

Based on the difference amount A3 between the calculated gain amount A2 calculated from the first peak voltage V1 and the second peak voltage V2 and the set gain amount A1 of the amplification unit 11, the FE circuit 2 controls the gain of the amplification unit 11 such that the maximum amplitude and the linearity of PAM4 after amplification are maintained. As a result, PAM4 that has the maximum signal amplitude and maintains the linearity while suppressing power consumption may be obtained.

The FE circuit 2 decreases the set gain amount A1 when the difference amount A3 between the calculated gain amount A2 and the set gain amount A1 exceeds the threshold value on the positive side. As a result, even when the difference amount A3 exceeds the threshold value on the positive side, PAM4 that has the maximum signal amplitude and maintains the linearity may be obtained.

The FE circuit 2 increases the set gain amount A1 when the difference amount A3 between the calculated gain amount A2 and the set gain amount A1 is less than the threshold value on the negative side, As a result, even when the difference amount A3 is less than the threshold value on the negative side, PAM4 that has the maximum signal amplitude and maintains the linearity may be obtained.

In the receiving device 1 of the present embodiment, as compared with the receiving device 100 of the comparative example, the signal level adjustment and the linear signal amplification may be implemented with low power consumption while the circuit configuration is simplified.

Note that, in the receiving device 1 of the present embodiment, PAM4 is exemplified as a multi-valued signal; however, the present embodiment is not limited to PAM4, and may be applied to, for example, multi-valued signals such as PAM6 and PAM8. In addition, modifications may be made as appropriate.

While the receiving device 1 in a case where the first detection unit 12, the second detection unit 13, and the control unit 14 are built in the FE circuit 2 has been exemplified, some of the first detection unit 12, the second detection unit 13, and the control unit 14 may be provided other than the FE circuit 2, and modifications may be made as appropriate.

Furthermore, each of the constituent elements of the units illustrated in the drawings is not necessarily physically configured as illustrated in the drawings. In other words, for example, specific forms of separation and integration of the respective units are not limited to the illustrated forms, and all or some of the units may be functionally or physically separated and integrated in an arbitrary unit according to various loads, use situations, and the like.

Moreover, all or some of various processing functions executed in the respective devices may be executed by a central processing unit (CPU) (or a microcomputer such as a micro processing unit (MPU) and a micro controller unit (MCU)). Furthermore, all or some of the various processing functions may of course be executed by a program analyzed and executed by a CPU (or a microcomputer such as an MPU and an MCU) or hardware using wired logic.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention,

What is claimed is:

1. A receiving device, comprising:
a memory; and
a processor coupled to the memory and configured to:
when amplifying a multi-valued signal of a multi-valued modulation technique according to a control signal, acquire a first multi-valued signal before amplifying the multi-valued signal and a second multi-valued signal after amplifying the multi-valued signal,
detect a first peak voltage of the first multi-valued signal,
detect a second peak voltage of the second multi-valued signal, and
control the control signal based on the first peak voltage and the second peak voltage such that a maximum amplitude of the second multi-valued signal and linearity of the second multi-valued signal are maintained.

2. The receiving device according to claim 1, wherein the processor is configured to
generate the control signal based on a difference between a calculated gain amount calculated from the first peak voltage and the second peak voltage, and a set gain amount.

3. The receiving device according to claim 2, wherein the processor is configured to
when a difference amount between the calculated gain amount and the set gain amount exceeds a threshold value on a positive side, generate the control signal to decrease the set gain amount

4. The receiving device according to claim 2, wherein the processor is configured to
when a difference amount between the calculated gain amount and the set gain amount is less than a threshold value on a negative side, generate the control signal to increase the set gain amount.

5. A receiving method executed by a computer, the receiving method comprising:
when amplifying a multi-valued signal of a multi-valued modulation technique according to a control signal, acquiring a first multi-valued signal before amplifying the multi-valued signal and a second multi-valued signal after amplifying the multi-valued signal;
detecting a first peak voltage of the first multi-valued signal;
detecting a second peak voltage of the second multi-valued signal; and
controlling the control signal based on the first peak voltage and the second peak voltage such that a maximum amplitude of the second multi-valued signal and linearity of the second multi-valued signal are maintained.

6. The receiving method according to claim 5, the receiving method further comprising generating the control signal based on a difference between a calculated gain amount calculated from the first peak voltage and the second peak voltage, and a set gain amount.

7. The receiving method according to claim 5, the receiving method further comprising
when a difference amount between the calculated gain amount and the set gain amount exceeds a threshold value on a positive side, generating the control signal to decrease the set gain amount

8. The receiving method according to claim 5, the receiving method further comprising
when a difference amount between the calculated gain amount and the set gain amount is less than a threshold value on a negative side, generating the control signal to increase the set gain amount.
